(19) United States
(12) Patent Application Publication
(10) Pub. No.: US 2005/0082637 A1
(43) Pub. Date: Apr. 21, 2005

(54) Dielectric memory and method for fabricating the same

(75) Inventors: Takumi Mikawa, Shiga (JP); Eiji Fujii, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD

(21) Appl. No.: 10/964,703

(22) Filed: Oct. 15, 2004

(30) Foreign Application Priority Data
Oct. 17, 2003 (JP) 2003-358212

(51) Int. Cl. H01L 21/8242; H01L 29/00

(52) U.S. Cl. 257/532; 438/957

(57) ABSTRACT

A semiconductor device is provided with an insulating film which is formed on a semiconductor substrate and has a first recess, a capacitor lower electrode which is formed on the walls and the bottom of the first recess and has a second recess, and a capacitor insulating film which is formed on the walls and the bottom of the second recess and has a third recess, and a capacitor upper electrode embedded in the third recess.

### CROSS-REFERENCE TO RELATED APPLICATIONS

The entire disclosure of Japanese Patent Application No. 2003-358212 filed on Oct. 17, 2003 including specification, drawings and claims are incorporated herein by reference.

### BACKGROUND OF THE INVENTION

The present invention relates to a semiconductor device provided with a capacitor element having a solid stack structure in which a dielectric film made of a dielectric material is used as a capacitor insulating film, and to a method for fabricating the same.

In the development of ferroelectric memories, small capacity ferroelectric memories of 1 to 64 Kbits adopting a planar structure are beginning to be in mass production, and recently, large capacity ferroelectric memories of 256 Kbits to 4 Mbits adopting a stack structure are in the core of the development. In ferroelectric memories with a stack structure, contact plugs electrically connecting with semiconductor substrates are disposed right under capacitor lower electrodes so as to improve the integration degree by reducing the cell size.

As miniaturization of ferroelectric memories advances, capacitor elements with a solid stack structure having so-called solid capacitor elements will be required, since it becomes difficult to secure charging amounts necessary for memory operation with planar capacitor elements. In order to realize a capacitor element with a solid stack structure, it is required to form a dielectric film and a capacitor upper electrode, having a fine coverage, on a capacitor lower electrode wnich is in a stepped shape and the surface area of which is increased. Conventionally, a capacitor element with a solid stack structure is realized by forming a capacitor lower electrode, a dielectric film and a capacitor upper electrode in a concave hole by using the CVD (for example, see Japanese Patent Application Laid-open No. 2003-7859A (page 8, FIG. 5)).

The structure of a semiconductor device provided with a capacitor element having a conventional solid stack structure will be described below with reference to FIG. 7.

As shown in FIG. 7, on a semiconductor device 100, there is formed a first interlayer insulating film 103 consisting of an oxide film 101 and a first antireflection film 102 made of a nitride film (SiON film). In the first interlayer insulating film 103, there are deposited a poly-silicon film 104 formed on the lower part of a storage contact hole communicating with an active region (not shown) of the semiconductor substrate 100, and a first and a second barrier metal films 105 and 106 formed on the poly-silicon film 104 and in the upper part of the storage contact hole. Note that the poly-silicon film 104 is formed by the chemical vapor deposition (CVD). The first and the second barrier metal films 105 and 106 serve to prevent an induction of poly-silicon oxidization on the boundary between a poly-silicon plug consisting of the poly-silicon film 104 and a storage electrode due to scattering of oxygen through the storage electrode, when a heat treatment is performed at a high temperature in the oxidant atmosphere.

Further, on the first interlayer insulating film 103, there is formed a second interlayer insulating film 110 consisting of an etching stopper film 107, an oxide film 108 and a second antireflection film 109. On the second interlayer insulating film 110, there are deposited a capacitor lower electrode 111 formed in the storage node hole and deposited by the CVD with a film thickness of 5 to 50 nm, a first BST thin film 112 deposited by the ALD (atomic layer deposition), a second BST thin film 113 deposited by the CVD, and a capacitor upper electrode 114 deposited by the CVD or sputtering. Note that the storage electrode is formed of the capacitor upper electrode 114 and the capacitor lower electrode 111.

In this way, a conventional semiconductor device realizes a miniaturized and highly integrated dielectric memory by being provided with a capacitor element with a solid stack structure in a concave solid shape.

### SUMMARY OF THE INVENTION

In the aforementioned conventional example, when a heat treatment is performed for crystallizing the dielectric film consisting of the first and the second BST thin films 112 and 113, there arises a problem that the upper capacitor electrode 114 is disconnected at a part having the worst step coverage near the bottom of the concave hole in the capacitor upper electrode 114. Further, the capacitor upper electrode 114 formed of a platinum film, which is used because of its compatibility to the dielectric films such as the first and the second BST films 112 and 113, easily causes stress-migrations due to the high ductility. Thereby, it is obvious that disconnections are frequently caused in the capacitor upper electrode 114 due to heat stress-migrations.

Further, although the crystallization temperature of the first and the second BST films 112 and 113, which are high dielectric films, is 500 to 700° C. and this crystallization temperature belongs to a relatively low temperature group, the crystallization temperature reaches 800° C. in some of the ferroelectric films, which is represented by an SBT film as a ferroelectric film. Thus, as the crystallization temperature becomes higher and the crystallization period becomes longer, the probability of failures such as disconnections being caused is expected to rise extremely.

In this case, the probability of heat stress-migrations may be reduced depending on a combination of a material used for the dielectric film and a material used for the capacitor upper electrode. However, as long as the probability of disconnections in the capacitor upper electrode remains even a little, a one bit failure cannot be solved in a large capacity memory.

In view of the above, an object of the present invention is to prevent in principle disconnections in a capacitor upper electrode constituting a capacitor element with a solid stack structure, without depending on a material used for a dielectric film and a material used for the capacitor upper electrode.

In order to solve the aforementioned problems, a semiconductor device of the present invention comprises: an insulating film which is formed on a semiconductor substrate and has a first recess; a capacitor lower electrode which is formed on the walls and the bottom of the first recess and has a second recess; a capacitor insulating film which is formed on the walls and the bottom of the second recess and has a third recess; and a capacitor upper electrode embedded in the third recess.

According to the semiconductor device of the present invention, the capacitor upper electrode is so formed as to be embedded in the third recess, whereby disconnections in the capacitor upper electrode can be prevented in principle. Thus, since the capacitor upper electrode fills the third recess, it is possible to avoid the stress being concentrated locally. Thereby, an influence of stress-migration is reduced, so that disconnections in the capacitor upper electrode can be prevented in principle. Therefore, it is possible to realize a capacitor element having a cell structure not causing disconnections in the capacitor upper electrode, without depending on a material used for the dielectric film and a material used for the capacitor upper electrode. This enables to provide a semiconductor device in which high integration can be achieved.

In the semiconductor device of the present invention, the first recess is desirably in a hole shape.

With this aspect, it is possible to realize a high-integrated semiconductor device of a concave type where no disconnection is caused in the capacitor upper electrode. Here, the hole shape of the first recess means an opening provided for each storage node contact.

In the semiconductor device of the present invention, the first recess is preferably in a groove shape.

With this aspect, it is possible to realize a high-integrated semiconductor device of a trench type where no disconnection is caused in the capacitor upper electrode. Further, since the first recess is in a groove shape, the solid angle to the side walls of the first recess is increased, whereby the embedding characteristics of the capacitor lower electrode, the capacitor insulating film and the capacitor upper electrode, against the first recess, the second recess, and the third recess are improved. Here, the groove shape of the first recess means an opening formed to be shared by a number of storage node contacts.

In the semiconductor device of the present invention, it is preferable that the capacitor lower electrode be formed only in the first recess, the capacitor insulating film be formed only in the second recess, and the capacitor upper electrode be formed only in the third recess.

With this aspect, the size of the capacitor element consisting of the capacitor lower electrode, capacitor insulating film and the capacitor upper electrode can be reduced, whereby the semiconductor device can be further miniaturized.

In the semiconductor device of the present invention, the capacitor upper electrode is preferably formed without generating hydrogen in the deposition atmosphere.

With this aspect, hydrogen will never intrude into the dielectric film constituting the capacitor insulating film when forming the capacitor upper electrode, whereby deterioration in the dielectric film due to hydrogen can be prevented.

In the semiconductor device of the present invention, the capacitor upper electrode is preferably formed by sputtering.

With this aspect, it is possible to realize a semiconductor device which is excellent in the throughput and also in the compatibility of the capacitor upper electrode to the dielectric film. Further, since the capacitor upper electrode can be formed while generation of hydrogen is suppressed, deterioration in the dielectric film due to hydrogen can be prevented.

In the semiconductor device of the present invention, the capacitor upper electrode is preferably formed by plating.

With this aspect, it is possible to realize an excellent step coverage equal to or greater than that of a case where the capacitor upper electrode is formed by the CVD. Further, since the capacitor upper electrode can be formed while generation of hydrogen is suppressed, deterioration in the dielectric film due to hydrogen can be prevented.

In the semiconductor device of the present invention, the capacitor upper electrode preferably contains a metal film.

The present invention adopts a structure in which disconnections are not caused in the capacitor upper electrode even if a metal film in which a stress-migration is easily caused is used, whereby a disconnection will never occur in the capacitor upper electrode containing a metal film. With this aspect, it is possible to use a metal film which is advantageous in the crystalline orientation of the dielectric film such as a platinum film, as a capacitor upper electrode.

A first method of fabricating a semiconductor device according to the present invention comprises the steps of: forming an insulating film with a first recess on a semiconductor substrate; forming a capacitor lower electrode consisting of a first conductive film with a second recess on the insulating film and on the walls and the bottom of the first recess; forming a capacitor insulating film consisting of a dielectric film with a third recess on the walls and the bottom of the second recess; and forming a capacitor upper electrode consisting of a second conductive film so as to fill the third recess.

According to the first method of fabricating a semiconductor device of the present invention, the capacitor upper electrode is so formed as to be embedded in the third recess.

Thereby, disconnections in the capacitor upper electrode can be prevented in principle. Thus, since the capacitor upper electrode fills the third recess, it is possible to avoid the stress being concentrated locally. Thereby, an influence of stress-migration is reduced, so that disconnections in the capacitor upper electrode can be prevented in principle.

Therefore, it is possible to realize a capacitor element with a cell structure not causing disconnections in the capacitor upper electrode without depending on a material used for the dielectric film and a material used for the capacitor upper electrode. Thereby, it is possible to provide a semiconductor device in which high integration can be realized.

A second method of fabricating a semiconductor device of the present invention comprises the steps of: forming an insulating film with a first recess on a semiconductor substrate; forming a first conductive film with a second recess on the insulating film and on the walls and the bottom of the first recess; forming a dielectric film with a third recess on the walls and the bottom of the second recess; forming a second conductive film so as to fill the third recess; and removing, by etching back or the CMP, portions of the first conductive film, of the dielectric film and of the second conductive film existing outside the first recess, to thereby form a capacitor lower electrode consisting of the first conductive film, a capacitor insulating film consisting of the dielectric film and a capacitor upper electrode consisting of the second conductive film.

According to the second method of fabricating a semiconductor device of the present invention, the capacitor upper electrode is so formed as to be embedded in the third recess. Thereby, disconnections in the capacitor upper electrode can be prevented in principle. Thus, since the capacitor upper electrode fills the third recess, it is possible to avoid the stress being concentrated locally. Thereby, an influence of stress-migration is reduced, so that disconnections in the capacitor upper electrode can be prevented in principle. Therefore, it is possible to realize a capacitor element with a cell structure not causing disconnections in the capacitor upper electrode without depending on a material used for the dielectric film and a material used for the capacitor upper electrode. Thereby, it is possible to provide a semiconductor device in which high integration can be realized. Further, since the portions of the first conductive film, of the dielectric film and of the second conductive film existing outside the first recess are removed to thereby form the capacitor lower electrode, the capacitor insulating film and the capacitor upper electrode, the size of the capacitor element can be reduced, so that the semiconductor device can be further miniaturized.

In the first or the second method of fabricating the semiconductor device of the present invention, the second conductive film (the capacitor upper electrode) is preferably deposited without generating hydrogen in the deposition atmosphere.

With this aspect, hydrogen will never intrude into the dielectric film constituting the capacitor insulating film when forming the capacitor upper electrode, whereby deterioration of the dielectric film due to hydrogen can be prevented.

In the first or the second method of fabricating the semiconductor device of the present invention, the second conductive film (the capacitor upper electrode) is preferably deposited by sputtering.

With this aspect, it is possible to realize a semiconductor device which is excellent in the throughput and also in the compatibility of the capacitor upper electrode to the dielectric film. Further, since the capacitor upper electrode can be formed while generation of hydrogen is suppressed, deterioration in the dielectric film due to hydrogen can be prevented.

In the first or the second method of fabricating the semiconductor device of the present invention, the second conductive film (the capacitor upper electrode) is preferably deposited by plating.

With this aspect, it is possible to realize an excellent step coverage equal to or greater than that of a case where the capacitor upper electrode is formed by the CVD. Further, since the capacitor upper electrode can be formed while generation of hydrogen is suppressed, deterioration in the dielectric film due to hydrogen can be prevented.

In the first or the second method of fabricating the semiconductor device of the present invention, the capacitor upper electrode (the second conductive film) preferably contains a metal film.

The present invention adopts a structure in which disconnections do not occur in the capacitor upper electrode even if a metal film in which stress-migrations are easily caused is used, whereby disconnections will never occur in the capacitor upper electrode containing a metal film. With this aspect, it is possible to use a metal film which is advantageous in the crystalline orientation of the dielectric film such as a platinum film, as a capacitor upper electrode.

As described above, according to the semiconductor device and the fabricating method therefor of the present invention, the capacitor upper electrode is so formed as to be embedded in the third recess. Thereby, disconnections in the capacitor upper electrode can be prevented in principle. Thus, since the capacitor upper electrode fills the third recess, it is possible to avoid the stress being concentrated locally. Thereby, an influence of stress-migration is reduced, so that disconnections in the capacitor upper electrode can be prevented in principle. Therefore, it is possible to realize a capacitor element with a cell structure not causing disconnections in the capacitor upper electrode without depending on a material used for the dielectric film and a material used for the capacitor upper electrode. Thereby, it is possible to provide a semiconductor device in which high integration can be realized.

### BRIEF DESCRIPTION OF THE DRAWINGS

FIG. 1A is a cross-sectional view showing a structure of a semiconductor device according to a first embodiment of the present invention, and FIG. 1B is a plan view showing the structure of the semiconductor device according to the first embodiment of the present invention.

FIGS. 2A to 2E are process sectional views showing a method of fabricating the semiconductor device according to the first embodiment of the present invention.

FIG. 3A is a cross-sectional view showing a structure of a semiconductor device according to a second embodiment of the present invention, and FIG. 3B is a plan view showing the structure of the semiconductor device according to the second embodiment of the present invention.

FIGS. 4A to 4E are process sectional views showing a method of fabricating the semiconductor device according to the second embodiment of the present invention.

FIG. 5 is a cross-sectional view showing a structure of a semiconductor device according to a third embodiment of the present invention.

FIGS. 6A to 6E are process sectional views showing a method of fabricating the semiconductor device according to the third embodiment of the present invention.

FIG. 7 is a cross-sectional view showing a structure of a conventional semiconductor device.

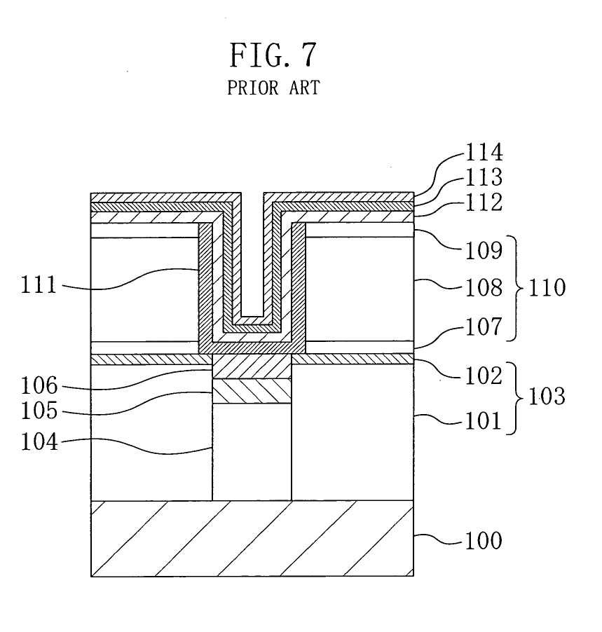

### PREFERRED EMBODIMENTS OF THE INVENTION

Hereinafter, preferred embodiments of the present invention will be described with reference to the accompanying drawings.

(FIRST EMBODIMENT)

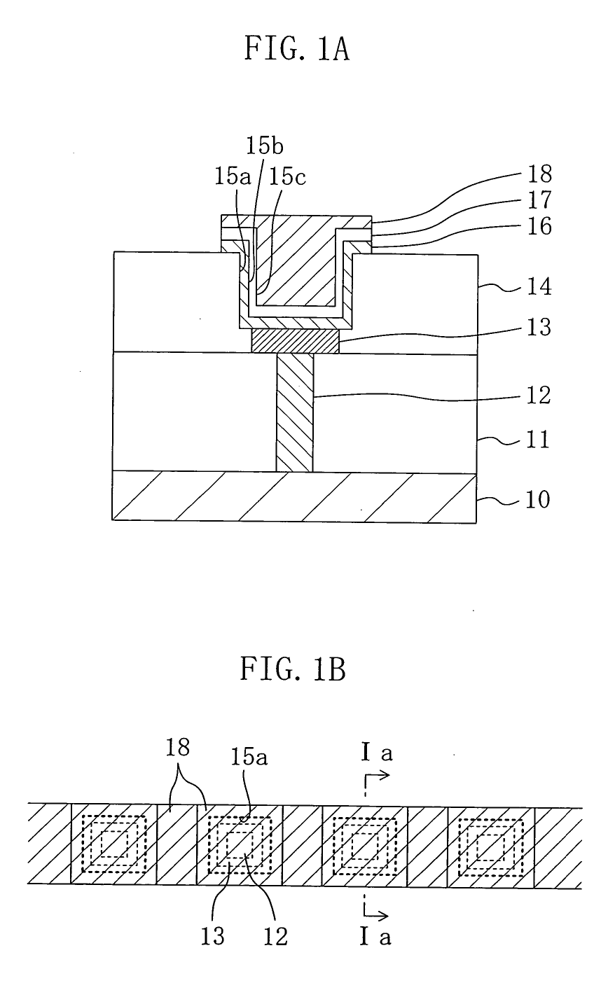

Hereinafter, a structure of a semiconductor device according to a first embodiment of the present invention will be described with reference to FIGS. 1A and 1B.

FIG. 1A is a cross-sectional view taken along the line Ia-Ia of FIG. 1B, showing a structure of a semiconductor device according to a first embodiment of the present invention, and FIG. 1B is a plan view showing the structure of the semiconductor device according to the first embodiment of the present invention.

As shown in FIG. 1A, on a semiconductor substrate 10, there is formed a first interlayer insulating film 11 consisting of a silicon oxide film with a thickness of 300 to 800 nm. In the first interlayer insulating film 11, there is formed a storage node contact 12 consisting of a tungsten film or a poly-silicon film, extending through the first interlayer insulating film 11 and communicating with an active region (not shown) of the semiconductor substrate 10. On the first interlayer insulating film 11, there is formed an oxygen barrier film 13 comprising an iridium film or an iridium oxide film or the like with 50 to 300 rin film thickness and connecting with the upper edge of the storage node contact 12. The oxygen barrier film 13 serves to prevent the storage node contact 12 from being oxidized when a dielectric film formed on top of the oxygen barrier film 13 is crystallized.

On the first interlayer insulating film 11, there is formed a second interlayer insulating film 14 consisting of a silicon oxide film with a thickness of 300 to 800 nm, surrounding the side faces of the oxygen barrier film 13 and having a first recess 15a. The first recess 15a is formed so as to penetrate the second interlayer insulating film 14 and to serve as an opening for forming a capacitor element, described later, which is provided for each storage node contact. The first recess 15a is in a hole shape. The hole shape of the first recess 15a means an opening provided for each storage node contact 12, as shown in FIG. 1B. Thereby, it is possible to realize a highly integrated semiconductor device of a concave type in which disconnections will not be caused in a capacitor upper electrode 18.

On top of the second interlayer insulating film 14 and on the walls and the bottom of the first recess 15a, there is formed a capacitor lower electrode 16 which consists of a platinum film with a thickness of 5 to 50 nm and has a second recess 15b. On top of the capacitor lower electrode 16 and on the walls and the bottom of the second recess 15b, there is formed a capacitor insulating film 17 which consists of an SBT film as a dielectric film with a thickness of 5 to 100 nm and has a third recess 15c. On top of the capacitor insulating film 17 and in the third recess 15c, a capacitor upper electrode 18 consisting of a platinum film is embedded. The capacitor upper electrode 18 is embedded in the third recess 15c so as to fill it up.

In the structure of the semiconductor device according to the first embodiment described above, the capacitor lower electrode 16, the capacitor insulating film 17 and the capacitor upper electrode 18 are formed by being patterned in a sectional drawing direction (vertical direction of the drawing) by using the same mask. However, they may be formed by using different masks, coping with the adhesion to the base film, the adhesion to the upper layered film, a problem of residue when processing, and the like.

Further, although the capacitor upper electrode 18 is formed to be shared by respective storage node contacts 12 in a lateral direction of the FIG. 1B, it may be formed for each storage node contact 12. Further, although the oxygen barrier film 13 is formed on the storage node contact 12, the oxygen barrier film 13 may not be formed, depending on the temperature (low temperature, for example) or the atmosphere (nitrogen atmosphere, for example) when crystallizing a dielectric film made of a metallic oxide of, for example, PZT series, BLT series, or BST series, besides an SBT series material.

As described above, according to the semiconductor device of the first embodiment of the present invention, the capacitor upper electrode 18 is so formed as to be embedded in the third recess 15c, whereby disconnections in the capacitor upper electrode 18 can be prevented in principle. Thus, since the capacitor upper electrode 18 fills the third recess 15c, it is possible to avoid the stress being concentrated locally. Thereby, an influence of stress-migration is reduced, so that disconnections in the capacitor upper electrode 18 can be prevented in principle. Therefore, it is possible to realize a capacitor element having a cell structure not causing disconnections in the capacitor upper electrode 18, without depending on a material used for the capacitor insulating film 17 and on a material used for the capacitor upper electrode 18. This enables to provide a semiconductor device in which high integration can be achieved.

Further, the semiconductor device according to the first embodiment of the present invention can prevent disconnections in the capacitor upper electrode 18 even when, for example, a heat treatment is preformed at 800° C. for crystallizing the capacitor insulating film 17.

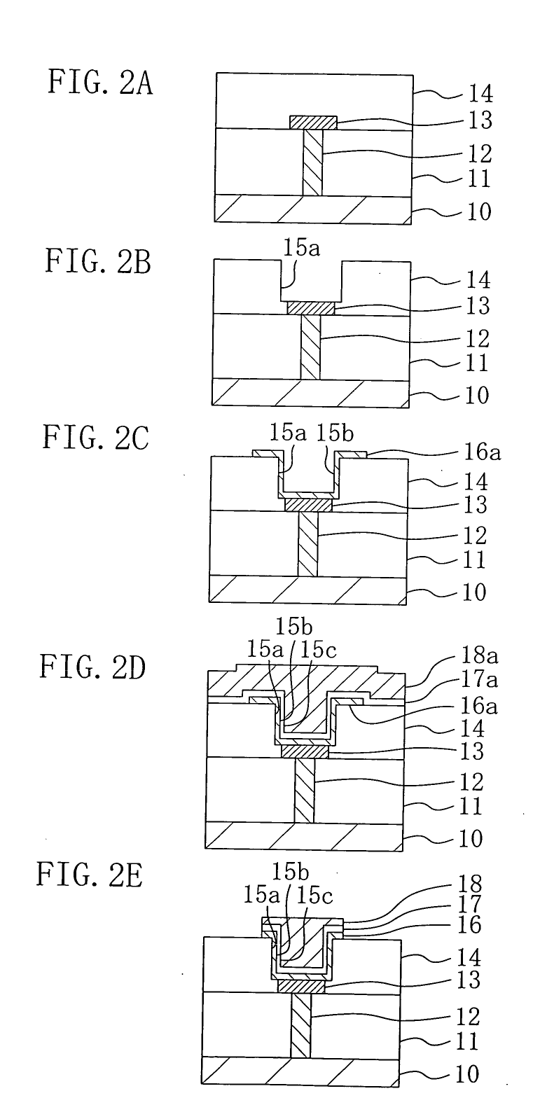

Hereinafter, a method for fabricating the semiconductor device according to the first embodiment of the present invention will be described with reference to FIGS. 2A to 2E.

First, as shown in FIG. 2A, on the semiconductor substrate 10, there is formed the first interlayer insulating film 11 consisting of a silicon oxide film with a thickness of 300 to 800 nm. Next, in the first interlayer insulating film 11, there is formed a storage node contact hole for exposing the surface of an active region (not shown) of the semiconductor substrate 10, and then the storage node contact hole is filled with a tungsten film or a poly-silicon film, to thereby form the storage node contact 12 extending through the first interlayer insulating film 11 and communicating with the active region of the semiconductor substrate 10.

Next, on the first interlayer insulating film 11, there is formed an oxygen barrier film 13 which comprises an iridium film or an iridium oxide film or the like with 50 to 300 nm film thickness, and connects with the upper edge of the storage node contact 12. The oxygen barrier film 13 servers to prevent the storage node contact 12 from being oxidized when the dielectric film formed on top of the oxygen barrier film 13 is crystallized.

Next, on the first interlayer insulating film 11, there is formed the second interlayer insulating film 14 consisting of a silicon oxide film with a thickness of 300 to 800 nm so as to cover the oxygen barrier film 13.

Then, as shown in FIG. 2B, there is formed the fist recess 15a penetrating through the second interlayer insulating film 14 and enabling an electrical connection with the oxygen barrier film 13 or with the storage node contact 12, by patterning the second interlayer insulating film 14 using a desired mask. Here, the first recess 15a formed in the second interlayer insulating film 14 is in a hole shape. The hole shape means an opening provided for each storage node contact 12 as shown in the FIG. 1B, as same as the one described above.

Next, as shown in FIG. 2C, on top of the second interlayer insulating film 14 and on the walls and the bottom of the first recess 15a, a first conductive film is deposited which consists of a platinum film with a thickness of 5 to 50 nm and has a second recess 15b, and then by patterning the first conductive film using a desired mask so as to electrically separate respective storage node contacts 12, the patterned first conductive film 16a is formed.

Next, as shown in FIG. 2D, on top of the second interlayer insulating film 14 and on top of the first conductive film 16a and on the walls and the bottom of the second recess 15b, an SBT film 17a is deposited as a dielectric film with a thickness of 5 to 100 nm having a third recess 15c by the CVD. Then, on the SBT film 17a, a second conductive film 18a consisting of a platinum film with a thickness of 50 to 300 nm is deposited so as to fill up the third recess 15c.

Next, as shown in FIG. 2E, etching back or the CMP is performed so as to cause the second conductive film 18a to be in a desired film thickness, and then the second conductive film 18a, the SBT film 17a, and the first conductive film 16a are patterned by using a desired mask, to thereby form the capacitor upper electrode 18 consisting of the second conductive film 18a, the capacitor insulating film 17 consisting of the SBT film 17a, and the capacitor lower electrode 16 consisting of the first conductive film 16a.

Here, although the capacitor lower electrode 16, the capacitor insulating film 17 and the capacitor upper electrode 18 are formed by patterning using the same mask, they may be formed by not using the same mask, coping with the adhesion to the base film, the adhesion to the upper layered film, a problem of the residue when processing, and the like, as same as the case described above. Further, the capacitor lower electrode 16 may be patterned to be in the final shape (see FIG. 2E) as the capacitor lower electrode 16, when the first conductive film 16a (see FIG. 2C) is formed. Further, although the second conductive film 18a is made to be in a desired film thickness by etching back or the CMP, the etching back or the CMP may not be needed if it is possible to form the second conductive film 18a to be in such a desired film thickness that the third recess 15c can be filled up exactly. Further, the capacitor element consisting of the capacitor lower electrode 16, the capacitor insulating film 17 and the capacitor upper electrode 18 may be formed by performing the etching back or the CMP to the first conductive film 16a, the SBT film 17a and the second conductive film 18a, which exist outside the first recess 15a, so as to expose the top surface of the second interlayer insulating film 14.

Further, although the capacitor upper electrode 18 is formed to be shared by respective storage node contacts 12 in the same way as described above, it may be provided for each storage node contact 12. Further, although the oxygen barrier film 13 is formed on the storage node contact 12, the oxygen barrier film 13 may not be formed, depending on the temperature (low temperature, for example) or the atmosphere (nitrogen atmosphere, for example) when crystallizing a dielectric film made of a metallic oxide of, for example, PZT series, BLT series, or BST series, besides an SBT series material.

As described above, according to the method for fabricating the semiconductor device of the first embodiment of the present invention, the capacitor upper electrode 18 is so formed as to be embedded in the third recess 15c, whereby disconnections in the capacitor upper electrode 18 can be prevented in principle. Thus, since the capacitor upper electrode 18 fills the third recess 15c, it is possible to avoid the stress being concentrated locally. Thereby, an influence of stress-migration is reduced, so that disconnections in the capacitor upper electrode 18 can be prevented in principle. Therefore, it is possible to realize a capacitor element having a cell structure not causing disconnections in the capacitor upper electrode 18, without depending on a material used for the capacitor insulating film 17 and a material used for the capacitor upper electrode 18. This enables to provide a semiconductor device in which high integration can be achieved.

Further, the semiconductor device according to the first embodiment of the present invention can prevent disconnections in the capacitor upper electrode 18 even when, for example, a heat treatment is preformed at 800° C. for crystallizing the capacitor insulating film 17.

(SECOND EMBODIMENT)

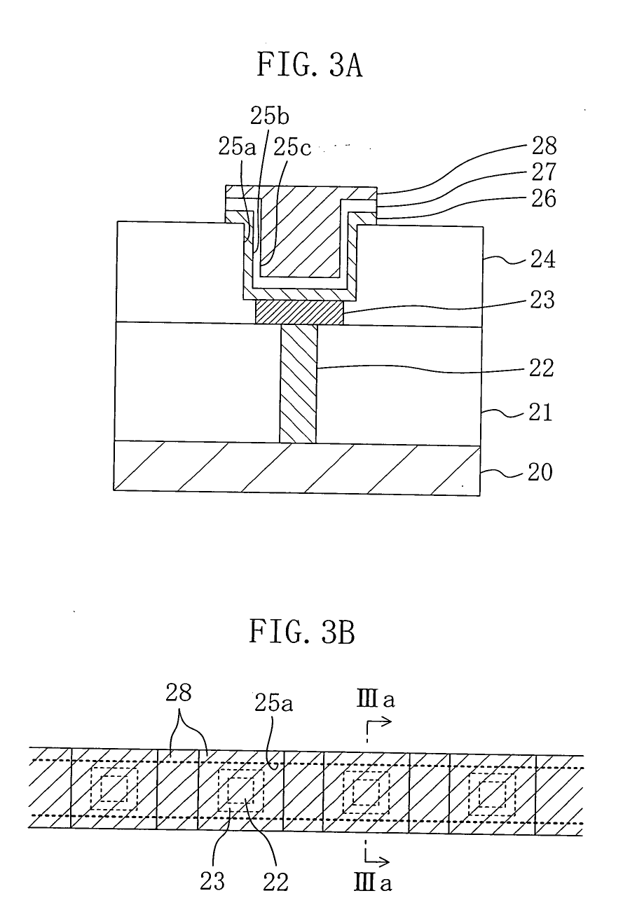

Hereinafter, the structure of a semiconductor device according to a second embodiment of the present invention will be described with reference to FIGS. 3A and 3B.

FIG. 3A is a cross-sectional view taken along the line IIIa-IIIa in FIG. 3B, showing the structure of a semiconductor device according to the second embodiment of the present invention, and FIG. 3B is a plan view showing the structure of the semiconductor device according to the second embodiment of the present invention.

As shown in FIG. 3A, on a semiconductor substrate 20, there is formed a first interlayer insulating film 21 consisting of a silicon oxide film with a thickness of 300 to 800 nm. In the first interlayer insulating film 21, there is formed a storage node contact 22 consisting of a tungsten film or a poly-silicon film, extending through the first interlayer insulating film 21 and communicating with an active region (not shown) of the semiconductor substrate 20. On the first interlayer insulating film 21, there is formed an oxygen barrier film 23 which comprises an iridium film or an iridium oxide film or the like with 50 to 300 nm film thickness and connects with the upper edge of the storage node contact 22. The oxygen barrier film 23 serves to prevent the storage node contact 22 from being oxidized when a dielectric film formed on the oxygen barrier film 23 is crystallized.

On the first interlayer insulating film 21, there is formed a second interlayer insulating film 24 consisting of a silicon oxide film with a thickness of 300 to 800 nm, which surrounds the side faces of the oxygen barrier film 23 and has a first recess 25a. The first recess 25a is formed so as to penetrate the second interlayer insulating film 24 and to serve as an opening for forming a capacitor element as described later such that it contains a plurality of storage node contacts 22. The first recess 25a is in a groove shape. Here, the groove shape of the first recess 25a means an opening provided to be shared by a plurality of storage node contacts 22, as shown in FIG. 3B. Thereby, it is possible to realize a highly integrated semiconductor device of a trench type in which disconnections will not be caused in a capacitor upper electrode 28.

On top of the second interlayer insulating film 24 and on the walls and the bottom of the first recess 25a, there is formed a capacitor lower electrode 26 which consists of a platinum film with a thickness of 5 to 50 nm and has a second recess 25b. On top of the capacitor lower electrode 26 and on the walls and the bottom of the second recess 25b, there is formed a capacitor insulating film 27 which consists of an SBT film as a dielectric film with a thickness of 5 to 100 nm and has a third recess 25c. On top of the capacitor insulating film 27 and in the third recess 25c, a capacitor upper electrode 28 consisting of a platinum film is embedded. The capacitor upper electrode 28 is embedded in the third recess 25c so as to fill it up exactly.

In the structure of the semiconductor device according to the second embodiment described above, the capacitor lower electrode 26, the capacitor insulating film 27 and the capacitor upper electrode 28 are formed by being patterned in a sectional drawing direction (vertical direction of the drawing) using the same mask. However, they may be formed by using different masks, coping with the adhesion to the base film, the adhesion to the upper layered film, a problem of residue when processing, and the like.

Further, although the capacitor upper electrode 28 is formed to be shared by respective storage node contacts 22 in a lateral direction of FIG. 3B, it may be provided for each storage node contact 22. Further, although the oxygen barrier film 23 is formed on the storage node contact 22, the oxygen barrier film 23 may not be formed, depending on the temperature (low temperature, for example) or the atmosphere (nitrogen atmosphere, for example) of crystallizing a dielectric film made of a metallic oxide of, for example, PZT series, BLT series, or BST series, besides an SBT series material.

As described above, according to the semiconductor device of the second embodiment of the present invention, the capacitor upper electrode 28 is so formed as to be embedded in the third recess 25c as same as the case of the first embodiment, whereby disconnections in the capacitor upper electrode 28 can be prevented in principle. Thus, since the capacitor upper electrode 28 fills the third recess 25c, it is possible to avoid the stress being concentrated locally. Thereby, an influence of stress-migration is reduced, so that disconnections in the capacitor upper electrode 28 can be prevented in principle. Therefore, it is possible to realize a capacitor element having a cell structure not causing disconnections in the capacitor upper electrode 28, without depending on a material used for the capacitor insulating film 27 and a material used for the capacitor upper electrode 28. This enables to provide a semiconductor device in which high integration can be achieved.

Further, according to the semiconductor device of the second embodiment of the present invention, the first recess 25a is in a groove shape. This increases the solid angle to the side walls of the first recess 25a, whereby the embedding characteristics of the capacitor lower electrode 26, the capacitor insulating film 27 and the capacitor upper electrode 28 against the first recess 25a, the second recess 25b, and the third recess 25c are improved.

Further, the semiconductor device according to the second embodiment of the present invention can prevent disconnections in the capacitor upper electrode 28 even when, for example, a heat treatment is preformed at 800° C. for crystallizing the capacitor insulating film 27.

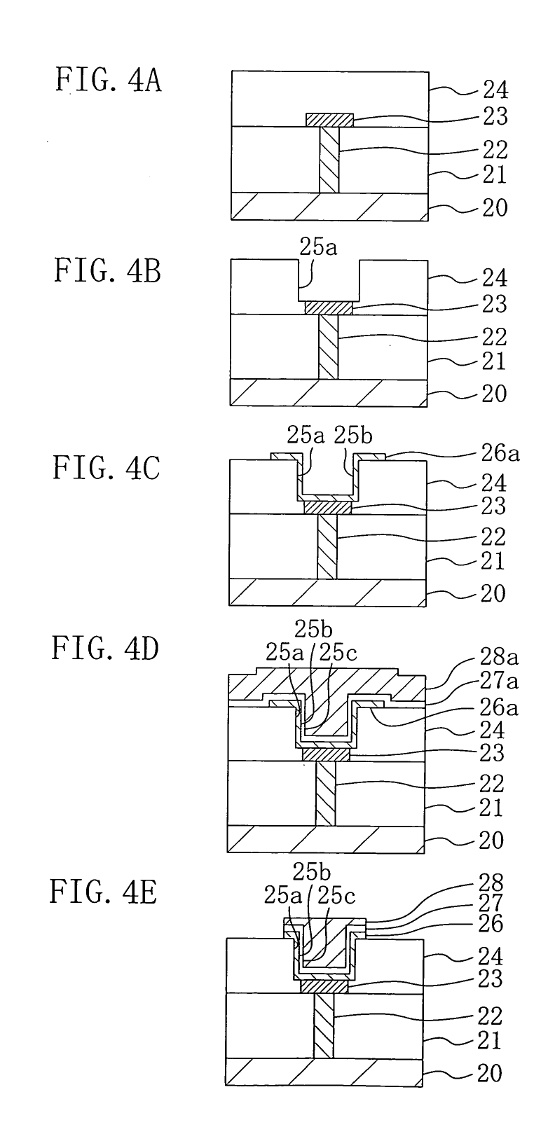

Hereinafter, a method for fabricating the semiconductor device according to the second embodiment of the present invention will be described with reference to FIGS. 4A to 4E.

First, as shown in FIG. 4A, on the semiconductor substrate 20, there is formed the first interlayer insulating film 21 consisting of a silicon oxide film with a thickness of 300 to 800 nm. Next, in the first interlayer insulating film 21, there is formed a storage node contact hole for exposing the surface of an active region (not shown) of the semiconductor substrate 20, and then the storage node contact hole is filled with a tungsten film or a poly-silicon film, to thereby form the storage node contact 22 extending through the first interlayer insulating film 21 and communicating with the active region of the semiconductor substrate 20.

Next, on the first interlayer insulating film 21, there is formed an oxygen barrier film 23 which comprises an iridium film or an iridium oxide film or the like with a thickness of 50 to 300 nm, and connects with the upper edge of the storage node contact 22. The oxygen barrier film 23 servers to prevent the storage node contact 22 from being oxidized when a dielectric film formed on top of the oxygen barrier film 23 is crystallized.

Next, on the first interlayer insulating film 21, there is formed the second interlayer insulating film 24 consisting of a silicon oxide film with a thickness of 300 to 800 nm so as to cover the oxygen barrier film 23.

Next, as shown in FIG. 4B, there is formed the fist recess 25a penetrating through the second interlayer insulating film 24 and enabling an electrical connection with the oxygen barrier film 23 or with the storage node contact 22, by patterning the second interlayer insulating film 24 using a desired mask. Here, the first recess 25a formed in the second interlayer insulating film 24 is in a groove shape. The groove shape means an opening formed to be shared by the respective storage node contacts 22 as shown in FIG. 2B, as same as the one described above.

Next, as shown in FIG. 4C, on top of the second interlayer insulating film 24 and on the walls and the bottom of the first recess 25a, a first conductive film is deposited which consists of a platinum film with a thickness of 5 to 50 nm and has a second recess 25b, and then by patterning the first conductive film using a desired mask so as to electrically separate respective storage node contacts 22, the patterned first conductive film 26a is formed.

Next, as shown in FIG. 4D, on top of the second interlayer insulating film 24 and on top of the first conductive film 26a and on the walls and the bottom of the second recess 25b, an SBT film 27a is deposited as a dielectric film with a thickness of 5 to 100 nm having a third recess 25c by the CVD. Then, on the SBT film 27a, a second conductive film 28a consisting of a platinum film with a thickness of 50 to 300 nm is deposited so as to fill up the third recess 25c.

Next, as shown in FIG. 4E, etching back or the CMP is performed so as to make the second conductive film 28a to be in a desired film thickness, and then the second conductive film 28a, the SBT film 27a, and the first conductive film 26a are patterned by using a desired mask to thereby form the capacitor upper electrode 28 consisting of the second conductive film 28a, the capacitor insulating film 27 consisting of the SBT film 27a, and the capacitor lower electrode 26 consisting of the first conductive film 26a.

Here, although the capacitor lower electrode 26, the capacitor insulating film 27 and the capacitor upper electrode 28 are formed by patterning using the same mask, they may be formed by not using the same mask, coping with the adhesion to the base film, the adhesion to the upper layered film, a problem of the residue when processing, and the like, as same as the case described above. Further, the capacitor lower electrode 26 may be patterned to be in the final shape (see FIG. 4E) as the capacitor lower electrode 26, when the first conductive film 26a (see FIG. 4C) is formed. Further, although the second conductive film 28a is made to be in a desired film thickness by etching back or the CMP, the etching back or the CMP may not be needed if it is possible to form the second conductive film 28a to be in such a desired film thickness that the third recess 25c can be filled up exactly. Further, the capacitor element consisting of the capacitor lower electrode 26, the capacitor insulating film 27 and the capacitor upper electrode 28 may be formed by performing the etching back or the CMP to the first conductive film 26a, the SBT film 27a and the second conductive film 28a existing outside the first recess 25a so as to expose the top surface of the second interlayer insulating film 24.

Further, although the capacitor upper electrode 28 is formed to be shared by respective storage node contacts 22 in the same way as described above, it may be provided for each storage node contact 22. Further, although the oxygen barrier film 23 is formed on the storage node contact 22, the oxygen barrier film 23 may not be formed, depending on the temperature (low temperature, for example) or the atmosphere (nitrogen atmosphere, for example) when crystallizing a dielectric film made of a metallic oxide of, for example, PZT series, BLT series, or BST series, besides an SBT series material.

As described above, according to the method for fabricating the semiconductor device of the second embodiment of the present invention, the capacitor upper electrode 28 is so formed as to be embedded in the third recess 25c as same as that of the first embodiment, whereby disconnections in the capacitor upper electrode 28 can be prevented in principle. Thus, since the capacitor upper electrode 28 fills the third recess 25c, it is possible to avoid the stress being concentrated locally. Thereby, an influence of stress-migration is reduced, so that disconnections in the capacitor upper electrode 28 can be prevented in principle. Therefore, it is possible to realize a capacitor element having a cell structure not causing disconnections in the capacitor upper electrode 28, without depending on a material used for the capacitor insulating film 27 and a material used for the capacitor upper electrode 28. This enables to provide a semiconductor device in which high integration can be achieved.

Further, according to the method for fabricating the semiconductor device of the second embodiment of the present invention, the first recess 25a is in a groove shape. This increases the solid angle to the side walls of the first recess 25a, whereby the embedding characteristics of the capacitor lower electrode 26, the capacitor insulating film 27 and the capacitor upper electrode 28 against the first recess 25a, the second recess 25b, and the third recess 25c are improved.

Further, the semiconductor device, formed in accordance with the method for fabricating the semiconductor device of the second embodiment of the present invention, can prevent disconnections in the capacitor upper electrode 28 even when, for example, a heat treatment is preformed at 800° C. for crystallizing the capacitor insulating film 27.

(THIRD EMBODIMENT)

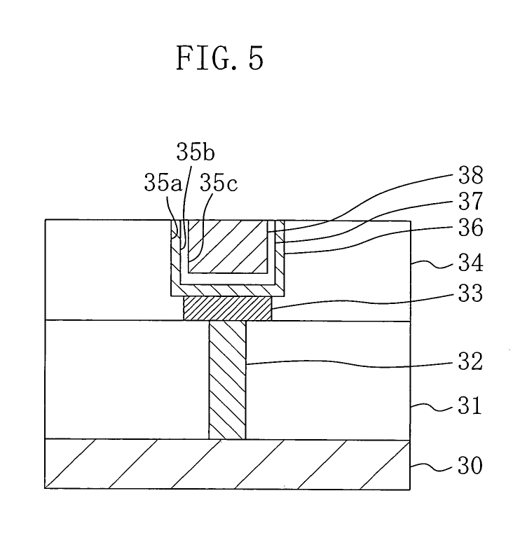

Hereinafter, the structure of a semiconductor device according to a third embodiment of the present invention will be described with reference to FIG. 5.

As shown in FIG. 5, on a semiconductor substrate 30, there is formed a first interlayer insulating film 31 consisting of a silicon oxide film with a thickness of 300 to 800 nm. In the first interlayer insulating film 31, there is formed a storage node contact 32 consisting of a tungsten film or a poly-silicon film, extending through the first interlayer insulating film 31 and communicating with an active region (not shown) of the semiconductor substrate 30. On the first interlayer insulating film 31, there is formed an oxygen barrier film 33 which comprises an iridium film or an iridium oxide film or the like with 50 to 300 nm film thickness and connects with the upper edge of the storage node contact 32. The oxygen barrier film 33 serves to prevent the storage node contact 32 from being oxidized when a dielectric film formed on top of the oxygen barrier film 33 is crystallized.

On the first interlayer insulating film 31, there is formed a second interlayer insulating film 34 consisting of a silicon oxide film with a thickness of 300 to 800 nm. surrounding the side faces of the oxygen barrier film 33 and having a first recess 35a. The first recess 35a is formed so as to penetrate the second interlayer insulating film 34 and to serve as an opening for forming a capacitor element, described later, which is provided for each storage node contact 32. The first recess 35a is in a concave shape.

On the walls and the bottom of the first recess 35a, there is formed a capacitor lower electrode 36 which consists of a platinum film with a thickness of 5 to 50 m and has a second recess 35b. On top of the capacitor lower electrode 36 and on the walls and the bottom of the second recess 35b, there is formed a capacitor insulating film 37 which consists of an SBT film as a dielectric film with a thickness of 5 to 100 nm and has a third recess 35c. On top of the capacitor insulating film 37 and in the third recess 35c, a capacitor upper electrode 38 consisting of a platinum film is embedded. The capacitor upper electrode 38 is embedded in the third recess 35c so as to fill it up exactly.

Further, the capacitor lower electrode 36 is formed only in the first recess 35a, the capacitor insulating film 37 is formed only in the second recess 35b, and the capacitor upper electrode 38 is formed only in the third recess 35c.

Further, the capacitor lower electrode 36 is only required to be separated from adjacent capacitor elements, and the capacitor insulating film 37 and the capacitor upper electrode 38 are not required to be separated from adjacent capacitor elements, although not shown. Therefore, in the semiconductor device of the third embodiment, the first recess 35a may be in a hole shape as the first embodiment, or may be in a groove shape as the second embodiment.

As described above, according to the semiconductor device of the third embodiment of the present invention, the capacitor upper electrode 38 is so formed as to be embedded in the third recess 35c as same as that of the first and the second embodiments, whereby disconnections in the capacitor upper electrode 38 can be prevented in principle. Thus, since the capacitor upper electrode 38 fills the third recess 35c, it is possible to avoid the stress being concentrated locally. Thereby, an influence of stress-migration is reduced, so that disconnections in the capacitor upper electrode 38 can be prevented in principle. Therefore, it is possible to realize a capacitor element having a cell structure not causing disconnections in the capacitor upper electrode 38, without depending on a material used for the capacitor insulating film 37 and a material used for the capacitor upper electrode 38. This enables to provide a semiconductor device in which high integration can be achieved.

Further, according to the semiconductor device of the third embodiment, the capacitor lower electrode 36 is formed only in the first recess 35a, the capacitor insulating film 37 is formed only in the second recess 35b, and the capacitor upper electrode 38 is formed only in the third recess 35c. Thereby, the capacitor element consisting of the capacitor lower electrode 36, the capacitor insulating film 37 and the capacitor upper electrode 38 can be reduced in size, which enables the semiconductor device to be further miniaturized.

Further, the semiconductor device according to the third embodiment of the present invention can prevent disconnections in the capacitor upper electrode 38 even when, for example, a heat treatment is preformed at 800° C. for crystallizing the capacitor insulating film 37.

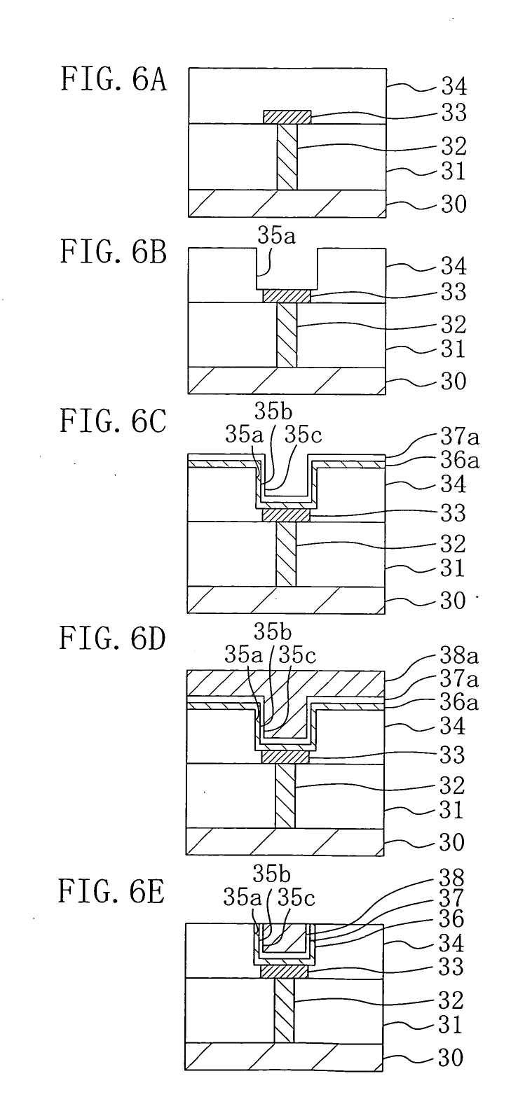

Hereinafter, a method for fabricating the semiconductor device according to the third embodiment of the present invention will be described with reference to FIGS. 6A to 6E.

First, as shown in FIG. 6A, on the semiconductor substrate 30, there is formed the first interlayer insulating film 31 consisting of a silicon oxide film with a thickness of 300 to 800 nm. Next, in the first interlayer insulating film 31, there is formed a storage node contact hole for exposing the surface of an active region (not shown) of the semiconductor substrate 30, and then the storage node contact hole is filled with a tungsten film or a poly-silicon film, to thereby form the storage node contact 32 extending through the first interlayer insulating film 31 and communicating with the active region of the semiconductor substrate 30.

Next, on the first interlayer insulating film 31, there is formed an oxygen barrier film 33 which comprises an iridium film or an iridium oxide film or the like with 50 to 300 nm film thickness and connects with the upper edge of the storage node contact 32. The oxygen barrier film 33 servers to prevent the storage node contact 32 from being oxidized when the dielectric film formed on top of the oxygen barrier film 33 is crystallized.

Next, on the first interlayer insulating film 31, there is formed the second interlayer insulating film 34 consisting of a silicon oxide film with a thickness of 300 to 800 nm so as to cover the oxygen barrier film 33.

Then, as shown in FIG. 6B, there is formed the first recess 35a penetrating through the second interlayer insulating film 34 and enabling an electrical connection with the oxygen barrier film 33 or with the storage node contact 32, by patterning the second interlayer insulating film 34 using a desired mask. Here, the first recess 35a formed in the second interlayer insulating film 34 is in a concave shape.

Next, as shown in FIG. 6C, on top of the second interlayer insulating film 34 and on the walls and the bottom of the first recess 35a, a first conductive film 36a is deposited which consists of a platinum film with a thickness of 5 to 50 nm and has a second recess 35b, and then the SBT film 37a is deposited as a dielectric film with a thickness of 5 to 100 nm having the third recess 35c by the CVD, over the whole surface of the first conductive film 36a.

Then, as shown in FIG. 6D, on the SBT film 37a, the second conductive film 38a consisting of a platinum film with a thickness of 50 to 300 nm is deposited by the CVD so as to fill up the third recess 35c.

Next, as shown in FIG. 6E, etching back or the CMP is performed to the second conductive film 38a, the SBT film 37a and the first conductive film 36a so as to expose the upper surface of the second interlayer insulating film 34 and to remove the portions of the second conductive film 38a, the SBT film 37a, and the first conductive film 36a which exist outside the first recess 35a, to thereby form the capacitor lower electrode 36 consisting of the first conductive film 36a, the capacitor insulating film 37 consisting of the SBT film 37b, and the capacitor upper electrode 38 consisting of the second conductive film 38c.

As described above, according to the method for fabricating the semiconductor device of the third embodiment of the present invention, the capacitor upper electrode 38 is so formed as to be embedded in the third recess 35c as same as that of the first and the second embodiments, whereby disconnections in the capacitor upper electrode 38 can be prevented in principle. Thus, since the capacitor upper electrode 38 fills the third recess 35c, it is possible to avoid the stress being concentrated locally. Thereby, an influence of stress-migration is reduced, so that disconnections in the capacitor upper electrode 38 can be prevented in principle. Therefore, it is possible to realize a capacitor element having a cell structure not causing disconnections in the capacitor upper electrode 38, without depending on a material used for the capacitor insulating film 37 and a material used for the capacitor upper electrode 38. This enables to provide a semiconductor device in which high integration can be achieved.

Further, according to the method for fabricating the semiconductor device of the third embodiment of the present invention, the capacitor lower electrode 36 is formed only in the first recess 35a, the capacitor insulating film 37 is formed only in the second recess 35b, and the capacitor upper electrode 38 is formed only in the third recess 35c. Thereby, the capacitor element consisting of the capacitor lower electrode 36, the capacitor insulating film 37 and the capacitor upper electrode 38 can be reduced in size, which enables the semiconductor device to be further miniaturized.

Moreover, the semiconductor device formed by the method for fabricating the semiconductor device of the third embodiment of the present invention can prevent disconnections in the capacitor upper electrode 38 even when, for example, a heat treatment is preformed at 800° C. for crystallizing the capacitor insulating film 37.

Further, in the aforementioned semiconductor devices according to the first to the third embodiments of the present invention and the fabricating method therefor, the capacitor upper electrode is preferably deposited by using a fabricating method which does not generate hydrogen in the deposition atmosphere.

In general, the CVD is widely used as a method for filling a recess where the aspect ratio is high. For example, in the CVD used when a platinum film is embedded in a recess, an organic source gas is typically used as a feed gas. In such a case, hydrogen is generated since the C-H group is decomposed during deposition. The hydrogen generated during deposition becomes active hydrogen in the condition of 500 to 600° C., or the deposition temperature, with an effect of the catalysis held by the platinum itself. This may cause a part of a dielectric film constituting the capacitor insulating film to be reduced. In this case, although it is possible to decrease the amount that the dielectric film being reduced due to the hydrogen by lowering the deposition temperature or by selecting a material having a less catalysis, it is difficult to completely eliminate the effect of the hydrogen on the dielectric film. Thus, it is preferable to form a capacitor upper electrode by using a fabricating method in which hydrogen is not generated in the deposition atmosphere so as to prevent degrading of the capacitor insulating film due to the hydrogen.

A specific fabricating method in which hydrogen is not generated in the deposition atmosphere will be described below.

First, it is preferable to form a capacitor upper electrode by sputtering.

In the first to third embodiments of the present invention, the capacitor upper electrode must be embedded in the third recess. For example, if the depth of the first recess is 300 run, the capacitor upper electrode must be deposited to have at least 150 nm film thickness in order to fill the third recess (practically, the capacitor upper electrode must be deposited to be in a film thickness of more than 150 nm, considering the dispersion caused in the walls and the bottom of the recess). In such a case, forming the capacitor upper electrode by the CVD is not considered as a preferable manner since the deposition rate is lower and the throughput is also degraded comparing with the case of using sputtering.

Alternatively, when forming the capacitor upper electrode by sputtering, high throughput of 25 pieces or more per hour can be maintained. Further, given the accumulation of the past actual data, the capacitor upper electrode deposited by the sputtering exhibits advantageous compatibility to dielectric films. Moreover, there is a wide know-how about the control method for depositing the capacitor upper electrode by sputtering. In view of this point, sputtering is considered as a very preferable method.

Further, although there are various methods for realizing embedding of the capacitor upper electrode in the third recess by using sputtering, the capacitor upper electrode can be embedded in the third recess by, for example, sputtering at a high temperature (the deposition temperature in about 500° C. or more, for example). For example, when depositing aluminum or the like at a high temperature by sputtering, the sputtered aluminum can be flowed so as to fill the recess by utilizing the deposition temperature. In other words, by sputtering a material used for the capacitor upper electrode at a high temperature and flowing it, it is possible to embed the capacitor upper electrode in the third recess. Thus, the third recess can be filled effectively by using a material having the low melting point and being easy to be flowed at a high temperature as a material used for the capacitor upper electrode.

Further, although high temperature sputtering can embed the capacitor upper electrode in the third recess regardless of the shape of the third recess, the capacitor upper electrode may be embedded in the third recess without high temperature sputtering, depending on the shape of the third recess. That is, if the third recess has a low aspect ratio (in a case where the opening of the third recess is large and the depth thereof is shallow), or if the walls of the third recess are tapered (in a case where the opening is increasing from the bottom to the top), the capacitor upper electrode can be embedded in the third recess by depositing it using the sputtering so as to be in a sufficient thickness. For example, in a case of sputtering being performed to have an a % coverage rate in the third recess where the diameter thereof is t, the capacitor upper electrode can be embedded in the third recess by depositing it so as to be in a film thickness of tx 100/2a.

It is also possible to embed the capacitor upper electrode in the third recess by depositing a noble metal including platinum or iridium by sputtering at a normal temperature (the deposition temperature is about 200 to 300° C., for example). When performing the sputtering at a normal temperature, although the embedding characteristics are degraded compared with the case of performing the sputtering at a high temperature, the capacitor upper electrode can be embedded sufficiently in the third recess, depending on the shape of the third recess. For example, if the third recess has a low aspect ratio (in a case where the opening of the third recess is large and the depth thereof is shallow), or if the walls of the third recess are tapered (in a case where the opening is increasing from the bottom to the top), it is well possible that the capacitor upper electrode is embedded in the third recess by sputtering a noble metal including platinum or iridium at a normal temperature.

Here, an explanation will be given for the crystalline structure of a metal constituting the capacitor upper electrode embedded in the third recess by the sputtering. First of all, the crystalline structure grown on the substrate surface is widely changed depending on the sputtering conditions such as a gas pressure, a temperature of the substrate surface, or a bias voltage. However, a characteristic common to the crystalline structure grown by using the present method in which a physical vapor deposition is performed, is that there are a number of lattice defects, called holes, causing the crystalline lattice orientation to be in the discontinuous state in the grain boundary including the initial layer. In particular, it is characterized that the grain boundary is easily grown in a direction vertical to the film thickness, and so-called columnar crystals are easily formed. A metal film constituting the capacitor upper electrode embedded in the third recess by the CVD is deposited in such a manner that the source gas is decomposed uniformly and carried to the substrate, and a desired atom is deposited selectively depending on the substrate temperature or the substrate bias, in the CVD. Thereby, an amorphous, lattice-combined thin film is grown to be deposited, without grain boundary defects observed in the case of PVD. This metal film is substantially different in the crystalline structure from a metal film constituting the capacitor upper electrode deposited by the sputtering.

Secondly, it is preferable to form a capacitor upper electrode by plating.

Plating is excellent in the embedding characteristics in principle. If the capacitor upper electrode is formed by plating, it is possible to realize the capacitor upper electrode having an excellent step coverage equal to or greater than the case of forming the capacitor upper electrode by the CVD. Further, deposition of the capacitor upper electrode using the plating contains no problem in the throughput.

It is preferable that a metal used for forming the capacitor upper electrode by plating be a noble metal such as a platinum film, iridium film or a rhodium film.

Here, an explanation will be given further for the crystalline structure of a metal constituting the capacitor upper electrode embedded in the third recess by plating. In general, it is characterized that granulated crystals are formed in the case of plating. However, when a heat treatment is performed, it is known that granulated crystals are combined to be a large plate crystal. Usually, a film processed through semiconductor processes has been exposed to a certain level of heat treatment, whereby it is often in the state where small granulated crystals and large plate crystals are mixed. A metal film constituting the capacitor upper electrode embedded in a third recess by the CVD is deposited in such a manner that an amorphous, lattice-combined thin film is grown without grain boundary defects observed in the case of PVD, as described above, whereby the metal film is substantially different in the crystalline structure from a metal film constituting an capacitor upper electrode deposited by the plating.

It should be noted that although hydrogen may be generated due to the electrolysis of water depending on the deposition conditions, the deposition temperature at which hydrogen is generated is in a very low range of 50 to 100° C. Therefore, it is also advantageous that a dielectric film constituting a capacitor insulting film is not affected by hydrogen.

Further, in the semiconductor device according to the first to the third embodiments of the present invention, it is preferable that at least a part of the capacitor upper electrode include a metal film. Since the present invention adopts a structure in which disconnections do not occur in the capacitor upper electrode even when using a metal film in which a stress-migration is easily caused, disconnections will not be caused in the capacitor upper electrode containing a metal film. Thereby, a metal film advantageous in the crystalline orientation of the dielectric film like a noble metal such as a platinum film, an iridium film or a rhodium film can be used in a part of the capacitor upper electrode.

It should be noted that the semiconductor device and the fabricating method therefor of the present invention can prevent in principle disconnections from being caused in a capacitor upper electrode formed in a recess, whereby they are effective in a ferroelectric memory or a high dielectric memory having a solid stack structure and using a dielectric material, and in a fabricating method therefor.

1. A semiconductor device, comprising:
an insulating film which is formed on a semiconductor substrate and has a first recess;
a capacitor lower electrode which is formed on a wall and a bottom of the first recess and has a second recess;
a capacitor insulating film which is formed on a wall and a bottom of the second recess and comprises a dielectric film with a third recess; and
a capacitor upper electrode embedded in the third recess.

2. The semiconductor device of claim 1, wherein the first recess is in a hole shape.

3. The semiconductor device of claim 1, wherein the first recess is in a groove shape.

4. The semiconductor device of claim 1, wherein the capacitor lower electrode is formed only in the first recess, the capacitor insulating film is formed only in the second recess, and the capacitor upper electrode is formed only in the third recess.

5. The semiconductor device of claim 1, wherein the capacitor upper electrode is formed without generating hydrogen in a deposition atmosphere.

6. The semiconductor device of claim 1, wherein the capacitor upper electrode is formed by sputtering.

7. The semiconductor device of claim 1, wherein the capacitor upper electrode is formed by plating.

8. The semiconductor device of claim 1, wherein the capacitor upper electrode contains a metal film.

9. A method of fabricating a semiconductor device, comprising the steps of:
forming an insulating film with a first recess on a semiconductor substrate;
forming a capacitor lower electrode comprising a first conductive film with a second recess on the insulating film and on a wall and a bottom of the first recess;
forming a capacitor insulating film comprising a dielectric film with a third recess on a wall and a bottom of the second recess; and
forming a capacitor upper electrode comprising a second conductive film so as to fill the third recess.

10. The method of fabricating the semiconductor device of claim 9, wherein the capacitor upper electrode is deposited without generating hydrogen in a deposition atmosphere.

11. The method of fabricating the semiconductor device of claim 9, wherein the capacitor upper electrode is deposited by sputtering.

12. The method of fabricating the semiconductor device of claim 9, wherein the capacitor upper electrode is deposited by plating.

13. The method of fabricating the semiconductor device of claim 9, wherein the capacitor upper electrode contains a metal film.

14. A method of fabricating a semiconductor device, comprising the steps of:
forming an insulating film with a first recess on a semiconductor substrate;
forming a first conductive film with a second recess on the insulating film and on a wall and a bottom of the first recess;
forming a dielectric film with a third recess on a wall and a bottom of the second recess;
forming a second conductive film so as to fill the third recess; and
removing, by etching back or a CMP, portions of the first conductive film, of the dielectric film and of the second conductive film existing outside the first recess, to thereby form a capacitor lower electrode comprising the first conductive film, a capacitor insulating film comprising the dielectric film, and a capacitor upper electrode comprising the second conductive film.

15. The method of fabricating the semiconductor device of claim 14, wherein the second conductive film is deposited without generating hydrogen in a deposition atmosphere.

16. The method of fabricating the semiconductor device of claim 14, wherein the second conductive film is deposited by sputtering.

17. The method of fabricating the semiconductor device of claim 14, wherein the second conductive film is deposited by plating.

18. The method of fabricating the semiconductor device of claim 14, wherein the second conductive film contains a metal film.
